(19) United States
(12) Patent Application Publication
(10) Pub. No.: US 2007/0170475 A1
(43) Pub. Date: Jul. 26, 2007

(54) MOUNTING STRUCTURE OF IMAGE PICKUP DEVICE

(76) Inventors: Naoki MATSUO, Tokyo (JP); Mamoru SAKASHITA, Okaya-shi (JP); Hiroshi TAKASUGI, Shiojiri-shi (JP)

Correspondence Address: OSTROLENK FABER GERB & SOFFEN, 1180 AVENUE OF THE AMERICAS, NEW YORK, NY, 100368403, US

(21) Appl. No.: 11/623,457

(22) Filed: Jan. 16, 2007

(30) Foreign Application Priority Data
Jan. 17, 2006 (JP) 2006-008852

(51) Int. Cl. H01L 31/113

(52) U.S. Cl. 257/291

(57) ABSTRACT

In a mounting structure of an image pickup device, an optical member allowing light to pass through is bonded to one side of an electric substrate with an adhesive with the image pickup device bonded to the other side of the electric substrate. In this structure, the hardness of an adhesive for bonding the image pickup device differs from the hardness of the adhesive for the optical member. The difference in hardness between the adhesives can reduce the influence of a difference in expansion coefficient between the image pickup device and the optical member. For example, the hardness of the adhesive for bonding the optical member can be set lower than that of the adhesive for bonding the image pickup device.

### CROSS-REFERENCE TO RELATED APPLICATION

This application is based upon and claims the benefit of priority from prior Japanese Patent Application No. 2006-008852, filed on Jan. 17, 2006, the entire contents of which are incorporated herein by reference.

### BACKGROUND OF THE INVENTION

1. Field of the Invention

The present invention relates to a mounting structure of an image pickup device, and more particularly, to an improvement in a mounting structure of an image pickup device to be fixed to a flexible substrate or the like.

2. Description of the Related Art

In general, in a single-lens reflex type digital camera (hereinafter simply referred to as “single-lens reflex camera”), an image pickup device such as a CCD (Charge Coupled Device) or the like is used to form a subject image. This image pickup device is mounted to a flexible substrate or the like. Further, on the front of the imaging surface of the image pickup device, a cover glass for preventing the intrusion of dust and the like is mounted to the flexible substrate or the like. The image pickup device and the cover glass are mounted to the flexible substrate or the like with adhesives, respectively.

For example, Japanese Patent No. 3207319 and Japanese Patent Laid-Open No. 08-84278 disclose an optical system using a flip-chip mounted image pickup device. It is also known a technique for pasting materials having different thermal coefficients together under high temperature conditions to curve an image pickup device using a difference in amount of shrinkage between the materials during a temperature drop (for example, see Japanese Patent Laid-Open No. 2004-349545).

However, in the above-mentioned prior art techniques, since the materials of the image pickup device and the cover glass are different in expansion coefficient upon flip-chip mounting of the image pickup device, a difference in amount of shrinkage between the image pickup device and the cover glass occurs during a temperature drop after pasted together under high temperature conditions.

FIG. 5 illustrates an example of such a conventional mounting structure of such an image pickup device, in which the upper part is a top view and the lower part is a sectional view.

On the back side of a flexible substrate 1 having a substantially square-shaped opening 2 (on the lower side in the sectional view of FIG. 5), an image pickup device 3 is pasted annularly with an image pickup device adhesive 4. On the other hand, on the front side of the flexible substrate 1 (on the upper side in the sectional view of FIG. 5), a cover glass 6 is pasted annularly with a cover glass adhesive 5. The image pickup device adhesive 4 and the cover glass adhesive 5 are applied around the periphery of the opening 2 of the flexible substrate 1.

### BRIEF SUMMARY OF THE INVENTION

The mounting structure of an image pickup device according to the present invention is such that the image pickup device is bonded on one side of an electric substrate and an optical member allowing light to pass through is bonded on the other side of the electric substrate, in which the adhesive for bonding the image pickup device differs in hardness from the adhesive for bonding the optical member.

The difference in hardness between the adhesives can reduce the influence of a difference in expansion coefficient between the image pickup device and the optical member.

For example, the hardness of the adhesive for bonding the optical member can be set lower than that of the adhesive for bonding the image pickup device. In general, since the mounting accuracy necessary for a light-transmissive optical member is lower than that necessary for an image pickup device, it is possible to use an adhesive having a lower hardness to bond the optical member. Thus, the elasticity of the adhesive for the optical member can reduce the influence of the difference in expansion coefficient between the image pickup device and the optical member.

As an exemplary structure of the present invention, a mounting structure of an image pickup device comprises: an electric substrate having an opening; an image pickup device bonded to the electric substrate with a first adhesive in such a manner to close the opening from one side of the electric substrate; and an optical member as a light-transmissive member bonded to the electric substrate with a second adhesive having a hardness different from that of the first adhesive in such a manner to close the opening from the other side of the electric substrate.

According to the present invention, there can be provided a mounting structure of an image pickup device with less adverse effects on images even if the image pickup device and the cover glass used are different in expansion coefficient.

The present invention can also be understood as the inventions of an imaging unit and an imaging apparatus.

### BRIEF DESCRIPTION OF THE SEVERAL VIEWS OF THE DRAWINGS

These and other features, aspects, and advantages of the apparatus and methods of the present invention will become better understood with regard to the following description, appended claims, and accompanying drawings where:

FIG. 1 is a perspective view illustrating the structure of a mirror box part of a digital single-lens reflex camera in which a mounting structure of an image pickup device according to a preferred embodiment of the present invention is applied;

FIG. 2 is a sectional view illustrating the structure of the mirror box part of the digital single-lens reflex camera in which the mounting structure of the image pickup device according to the embodiment of the present invention is applied;

FIG. 3 is a top view illustrating the structure of the mirror box part of the digital single-lens reflex camera in which the mounting structure of the image pickup device according to the embodiment of the present invention is applied, wherein the arrangement of an aluminum plate 15, a protective member 16, a flexible substrate 17, an image pickup device 21, etc. is illustrated; and

FIG. 4 is a sectional view enlargedly illustrating a bonding section of the image pickup device 21 and a cover glass 24 to the flexible substrate 17 shown in FIG. 2;

FIG. 5 contains a top view and a sectional view illustrating an example of a conventional mounting structure of an image pickup device.

### DETAILED DESCRIPTION OF THE PREFERRED EMBODIMENT

A preferred embodiment of the invention is described below with reference to the accompanying drawings.

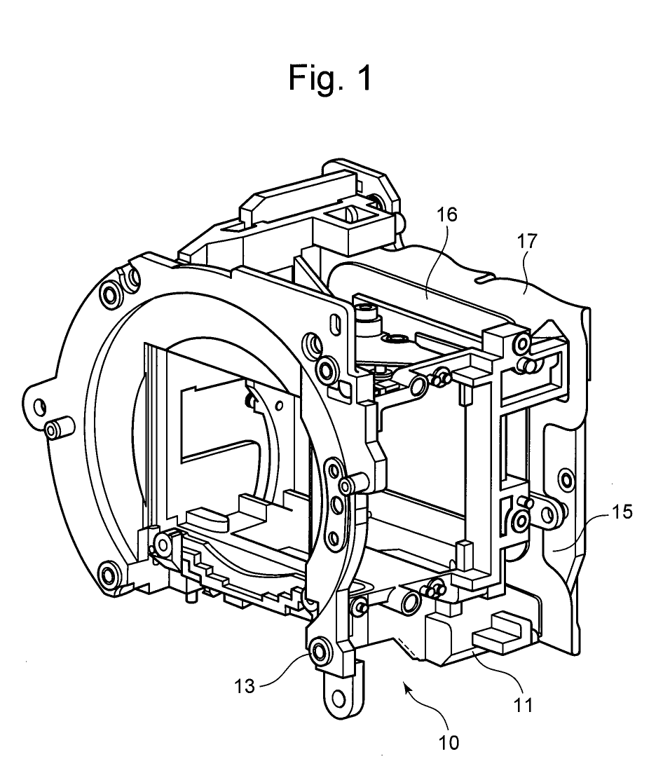

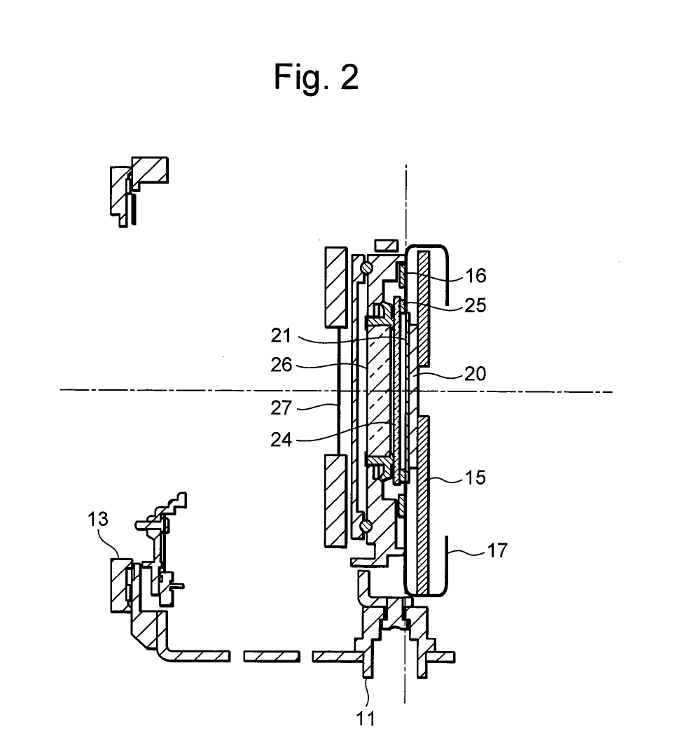

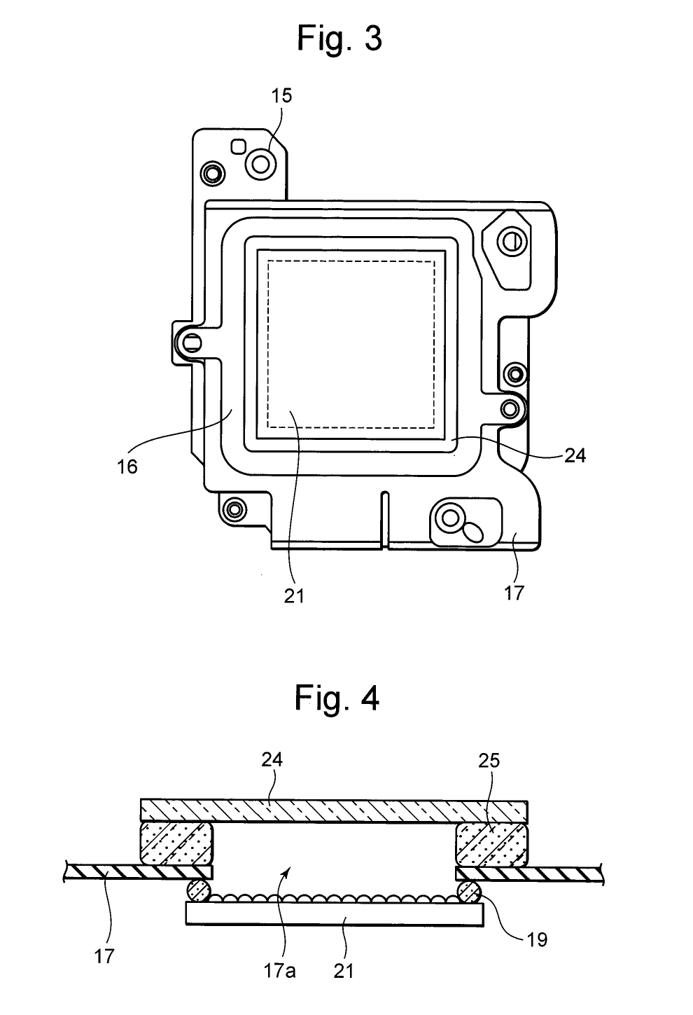

FIGS. 1 and 2 illustrate the structure of a mirror box part of a digital single-lens reflex camera as an imaging apparatus in which a mounting structure of an image pickup device according to a preferred embodiment of the present invention is applied. FIG. 1 is a perspective view and FIG. 2 is a sectional view of the mirror box part of FIG. 1. Further, FIG. 3 is a top view as an imaging unit, illustrating the arrangement of an aluminum plate 15, a protective member 16, a flexible substrate 17, an image pickup device 21, etc.

In FIGS. 1 and 2, a mirror box 10 has a body section 11 and a mount part 13 as the front part of the body section 11. The mount part 13 is a part on which a lens barrel (not shown) is mounted and retained on its optical axis. Then, various components of an imaging part including an image pickup device to be described later are assembled behind the mount part 13 in the body section 11.

A protective member 16 is made of a plate material and used to protect the adhesive surfaces of the image pickup device 21 and a cover glass 24 from the influence of bending of the flexible substrate 17 as an electric substrate and to position them when assembled in the camera body. The protective member 16 is fastened with screws (not shown) to the aluminum plate 15 through the flexible substrate 17. This aluminum plate 15 is also used as a reference to position the entire mirror box 10.

The image pickup device 21 is composed of a CCD and the like, and has a tiny flat-plate shape to obtain an image signal corresponding to light passing through a photographing optical system (not shown) and irradiated to its photoelectric conversion surface. This image pickup device 21 is bonded to the backside of the flexible substrate 17 with an adhesive to be described later from the rear side of the body section 11. Upon bonding, a pin-like protrusion or bump (not shown) provided on each aluminum electrode of the image pickup device 21 is brought into press-contact with a connector portion of the flexible substrate 17 due to the shrinkage of the adhesive, thereby securing electric conduction between both. The flexible substrate 17 is connected on the imaging surface side of the image pickup device 21. The flexible substrate 17 supplies the image signal photoelectrically converted from light and acquired by the image pickup device 21 to an electric circuit such as an image processing circuit, not shown.

On the opposite side of the imaging surface of the image pickup device 21, a heat sink or radiator plate 20 made, for example, from ceramic for releasing heat accumulated in the image pickup device 21 is mounted. The radiator plate 20 is mounted on the above-mentioned aluminum plate 15, thus retaining the image pickup device 21 in the body section 11 of the mirror box 10.

Further, on the imaging surface side of the image pickup device 21, the cover glass 24 as an optical member, a low pass filter (hereinafter abbreviated as “LPF”) 26, and a shutter 27 are arranged in order. The cover glass 24 has a flat-plate shape and made of a light-transmissive glass for protecting the imaging surface of the image pickup device 21. The LPF 26 removes high frequency components from a subject light flux irradiated thereto after passing through the photographing optical system (not shown). The shutter 27 controls the irradiation time and the like of the subject light flux to the imaging surface of the image pickup device 21. Note that the cover glass 24 may be replaced by a material made from acrylic resin (PMMA) as required in optical design.

FIG. 4 is a sectional view enlargedly illustrating a bonding section of the image pickup device 21 and a cover glass 24 to the flexible substrate 17 shown in FIG. 2.

The flexible substrate 17 has a substantially square-shaped opening 17a. An image pickup device adhesive 19 is applied annularly around the periphery of this opening 17a on the back side of the flexible substrate 17 (on the lower side in FIG. 4). On the other hand, a cover glass adhesive 25 is applied annularly on the front side of the flexible substrate 17 (on the upper side in FIG. 4). The hardness of the cover glass adhesive 25 is set lower than the hardness of the image pickup device adhesive 19.

The following describes about the hardness of adhesives.

Upon bonding the image pickup device 21 to the flexible substrate 17, it is desirable to bond it firmly with an adhesive having a high hardness in order to improve adhesive position accuracy. On the other hand, for bonding the cover glass 24, it is desirable to use an adhesive having a lower hardness (that is, an adhesive having elasticity). The reason will be described below.

As mentioned above, since the cover glass typically has a high thermal shrinkage rate, the amount of shrinkage (or expansion) increases as the temperature changes. The occurrence of this shrinkage (or expansion) could cause the image pickup device to be deformed.

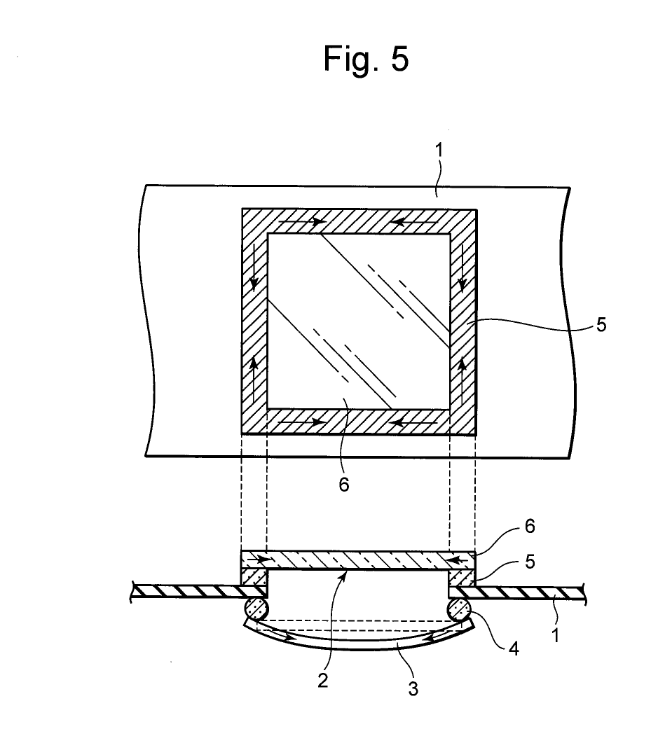

This deformed state is shown in the sectional view of FIG. 5, which illustrates the conventional mounting structure of the image pickup device as mentioned above. In general, since the cover glass 6 has a high thermal shrinkage rate compared to a chip on which the image pickup device 3 is mounted, the amount of shrinkage (or expansion) in the cover glass 6 increases as the temperature changes. Therefore, as the cover glass 6 shrinks or expands, a stress is exerted as indicated by arrows in FIG. 5 (a stress produced upon shrinkage of the cover glass 6 is illustrated in FIG. 5). As a result, the image pickup device 3 having a lower thermal shrinkage rate than the cover glass 6 can deflect, for example, from the state indicated by the broken line to the state indicated by the solid line in the sectional view of FIG. 5. This could cause the image surface to be deformed.

In this case, if an adhesive, which is likely to produce shear strain against the shearing force generated by the shrinkage of the cover glass, that is, an elastic adhesive (having a low hardness) is used, the deformation of the image pickup device can be reduced. Note that, since the cover glass does not need to improve adhesion accuracy, use of an adhesive having a low hardness does not cause much problem.

However, since the deformation of the image pickup device is affected by various other factors, such as the shrinkage rate of the cover glass, the hardness of the image pickup device chip, etc., it is difficult to define the kind of adhesive for the cover glass.

Therefore, from the results of experiments using common cover glasses, flexible substrates, image pickup devices, and adhesives for the image pickup devices, it was found that the image pickup device cannot be deformed in case of use of an adhesive within a range of Shore hardnesses of about A80 to A40 defined in Japanese Industrial Standards (JIS).

On the other hand, upon bonding the image pickup device chip, the image pickup device chip can be fixed firmly with an adhesive having a relatively higher hardness than the adhesive for the cover glass, for example, having a hardness of D80 or more defined in Japanese Industrial Standards (JIS). This fixation can prevent positional displacement of the image pickup device, and further prevent electrical disconnection between the image pickup device and the flexible substrate to secure electrical connection therebetween.

To sum up, it is desirable to use an adhesive with JIS A-type hardness for the cover glass and an adhesive with JIS D-type hardness for the image pickup device chip. For example, it is effective to use a UV acrylic adhesive as the adhesive for the cover glass and an NCP as an epoxy type thermoset adhesive for the image pickup device.

In addition, if moisture is entered in an airspace between the image pickup device chip and the cover glass, the surface of the cover glass and the imaging surface of the image pickup device could get clouded, or water droplets could adhere thereto. Therefore, it is desirable to seal the airspace hermetically using a moisture-proof type for each adhesive.

Thus, in the embodiment, the cover glass adhesive 25 lower in hardness than the image pickup device adhesive 19 is used to bond the flexible substrate 17 and the cover glass 24. Therefore, even if the cover glass 24 is deformed by stress, since the cover glass adhesive 25 absorbs the stress, thereby making it possible to minimize the deformation of the image pickup device 21.

Further, the use of the cover glass adhesive 25 hardened at room temperature to bond the flexible substrate 17 and the cover glass 24 eliminates the need to apply heat upon curing, thereby making it possible to minimize the deformation of the image pickup device 21.

Although the aforementioned embodiment takes a single-lens reflex camera as an example, the present invention is not limited thereto and is applicable to any other imaging apparatus such as a digital camera with an image pickup device mounted therein.

While there has been shown and described what are considered to be preferred embodiments of the invention, it will, of course, be understood that various modifications and changes in form or detail could readily be made without departing from the spirit of the invention. It is therefore intended that the invention not be limited to the exact forms described and illustrated, but constructed to cover all modifications that may fall within the scope of the appended claims.

What is claimed is:

1. A mounting structure of an image pickup device comprising:
an electric substrate having an opening;
an image pickup device bonded to the electric substrate with a first adhesive in such a manner to close the opening from one side of the electric substrate; and
an optical member bonded to the electric substrate with a second adhesive having a hardness different from that of the first adhesive in such a manner to close the opening from the other side of the electric substrate.

2. The mounting structure of the image pickup device according to claim 1, wherein the hardness of the second adhesive is lower than the hardness of the first adhesive.

3. The mounting structure of the image pickup device according to claim 1, wherein the hardness of the first adhesive is higher than the hardness of the second adhesive.

4. The mounting structure of the image pickup device according to claim 1, wherein the second adhesive is applied annularly around the periphery of the optical member.

5. The mounting structure of the image pickup device according to claim 1, wherein the optical member is made of a glass material.

6. The mounting structure of the image pickup device according to claim 1, wherein the electric substrate is a flexible substrate.

7. An imaging unit comprising:
an electric substrate having an opening;
an image pickup device bonded to the electric substrate with a first adhesive in such a manner to close the opening from one side of the electric substrate; and
an optical member as a light-transmissive member bonded to the electric substrate with a second adhesive having a hardness different from that of the first adhesive in such a manner to close the opening from the other side of the electric substrate.

8. The imaging unit according to claim 7, wherein the hardness of the second adhesive is lower than the hardness of the first adhesive.

9. The imaging unit according to claim 7, wherein the hardness of the first adhesive is higher than the hardness of the second adhesive.

10. The imaging unit according to claim 7, wherein the second adhesive is applied annularly around the periphery of the optical member.

11. The imaging unit according to claim 7, wherein the optical member is made of a glass material.

12. The imaging unit according to claim 7, wherein the electric substrate is a flexible substrate.

13. An imaging apparatus comprising:
an electric substrate having an opening;
an image pickup device bonded to the electric substrate with a first adhesive in such a manner to close the opening from one side of the electric substrate; and
an optical member bonded to the electric substrate with a second adhesive having a hardness different from that of the first adhesive in such a manner to close the opening from the other side of the electric substrate.

14. The imaging apparatus according to claim 13, wherein the hardness of the second adhesive is lower than the hardness of the first adhesive.

15. The imaging apparatus according to claim 13, wherein the hardness of the first adhesive is higher than the hardness of the second adhesive.

16. The imaging apparatus according to claim 13, wherein the second adhesive is applied annularly around the periphery of the optical member.

17. The imaging apparatus according to claim 13, wherein the optical member is made of a glass material.

18. The imaging apparatus according to claim 13, wherein the electric substrate is a flexible substrate.
